(19) United States
(12) Patent Application Publication
(10) Pub. No.: US 2021/0252602 A1
(43) Pub. Date: Aug. 19, 2021

(54) MOUNTS FOR MICRO-MIRRORS

(71) Applicant: Hewlett-Packard Development Company, L.P., Spring, TX (US)

(72) Inventor: Seongsik Chang, Palo Alto, CA (US)

(73) Assignee: Hewlett-Packard Development Company, L.P., Spring, TX (US)

(21) Appl. No.: 17/056,211

(22) PCT Filed: Oct. 23, 2018
(86) PCT No.: PCT/US2018/056994

§ 371 Date: Nov. 17, 2020

(51) Int. Cl. B22F 12/44; G02B 26/08; G02B 7/18; B81B 7/00; B33Y 30/00

(52) U.S. Cl. CPC B22F 12/44; G02B 26/0841; G02B 7/1815; B41J 2/435; B33Y 30/00; B81B 2201/042; B81B 7/0087

(57) ABSTRACT

Mounts for micro-mirrors are disclosed. A disclosed example apparatus includes a micro-mirror having a reflective surface area, and a movable mount to support and move the micro-mirror to direct light onto a printing area, where the movable mount includes a cross-sectional profile area that is at least 30% of the reflective surface area of the micro-mirror.

### BACKGROUND

Digital micro-mirror devices are used in projection technology, such as video or image displays. Digital micro-mirror devices utilize an array of micro-mirrors that can be moved to reflect and/or aim light from a light source to produce images or video to be projected onto a surface. Micro-mirrors are typically attached to a movable mount so that the light reflected from the micro-mirrors can be aimed toward an area, object and/or location.

### BRIEF DESCRIPTION OF THE DRAWINGS

FIG. 1 is a digital micro-mirror device printing system in which examples disclosed herein can be implemented.

FIG. 2 is detailed view of an example micro-mirror array in accordance with the teachings of this disclosure.

FIG. 3 is an exploded detailed view of one of the micro-mirror assemblies of the example micro-mirror array of FIG. 2.

FIG. 4 is a schematic diagram of the example micro-mirror assembly of the example micro-mirror array of FIG. 2.

The figures are not to scale. Instead, the thickness of the layers or regions may be enlarged in the drawings. In general, the same reference numbers are used throughout the drawing(s) and accompanying written description to refer to the same or like parts.

### DETAILED DESCRIPTION

Digital micro-mirror device (DMD) systems employ an array of movable micro-mirrors to reflect and/or aim light. For example, the light is generated by a light source and reflected from the micro-mirrors during image projection. Light intensity and/or light properties of light emitted toward and reflected from the micro-mirrors can vary an amount of energy absorbed by the micro-mirrors and, thus, temperatures of the micro-mirrors. In particular, absorption of high intensity light can cause significant heat to the micro-mirrors and, thus, may damage or impair the micro-mirrors. Some DMD implementations employ relatively small (e.g., thin) mounts to facilitate rapid movement of corresponding micro-mirrors coupled thereto for image or video projection. However, such relatively small mounts do not provide an effective cooling path for the respective micro-mirrors.

Example mounts for micro-mirrors disclosed herein provide an effective cooling of the micro-mirrors associated with a DMD used in conjunction with high intensity light. These examples prevent damage and/or degradation to the DMD (e.g., melting of the micro-mirrors). Examples disclosed herein provide a highly conductive thermal pathway to the cool micro-mirrors of the DMD, thereby enabling use of relatively high intensity light. The high intensity light can be used for three-dimensions (3-D) metal printing and/or additive part manufacturing known as photonic fusion, for example. In some examples, 3-D metal printing processes use high intensity light with a peak intensity of approximately 10 kilowatt per centimeter squared, which can result in a large amount of heat generated in the micro-mirrors due to light absorption. Examples disclosed herein utilize a movable micro-mirror mount (e.g., a movable heatsink) with a cross-sectional area (e.g., a cross-sectional profile area, a total effective cross-sectional area, etc.) that is at least 30% of a reflective surface area of a corresponding micro-mirror mounted thereto. Accordingly, the micro-mirror can dissipate relatively large amounts of heat. However, movement of the micro-mirror can be relatively slow in comparison to typical image/video projection applications. This relatively slower movement is acceptable for printing applications that do not necessitate relatively quick motion, such as layer-by-layer additive printing processes, for example.

As used herein, the term “mount” refers to a structure or assembly used to support and/or move another object. Accordingly, the term “movable mount” refers to a structure or assembly that can be moved to orient, translate and/or displace another object coupled thereto. As used herein, the term “light source” refers to a light generating/emitting component or assembly, which can be separate from or part of a printing system, for example. Further, the light emitted and/or generated by the light source can be infrared (IR), visible, ultra-violet (UV), etc.

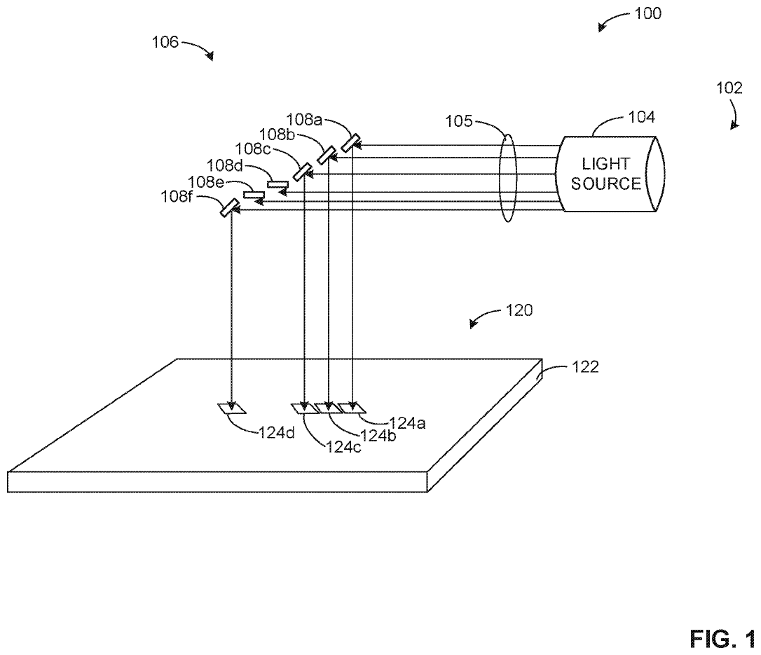

FIG. 1 is a DMD printing system (e.g., a printer, an additive printer, a 3-D printer, etc.) 100 in which examples disclosed herein can be implemented. In this example, the DMD printing system 100 is implemented as a 3-D additive manufacturing printer. The DMD printing system 100 of the illustrated example includes a light projection system 102 which, in turn, includes a light source 104, a lens (e.g., a movable lens) 105 and a micro-mirror array 106. The example micro-mirror array 106 includes micro-mirror assemblies 108 (108a, 108b, 108c, 108d, 108e, 108f). In this example, the light projection system 102 is located proximate a print area 120, which includes a print bed (e.g., a powder print bed, a metal powder bed, etc.) 122.

In operation, the light source 104 of the illustrated example transmits light toward the micro-mirror assemblies (e.g., micro-mirror devices,movable micro-mirrors, discrete micro-mirrors, etc.) 108. For example, the light is a relatively high intensity light with an intensity that is approximate to or exceeds 1 kilowatt per centimeter squared. In this example, the micro-mirror assemblies 108a, 108b, 108c, 108f are angled to reflect the light from the light source 104 toward the print bed 122. In particular, each ones of the micro-mirror assemblies 108 are independently moved and/or controlled. As a result, a print pattern having light incident regions 124a, 124b, 124c, 124d, respectively, is defined.

In particular, the light incident regions 124a, 124b, 124c, 124d represent areas in which the metal powder is fused to at least partially define a solid object (e.g., a metal object) being printed by the DMD printing system 100. In other words, the example printing process implemented by the DMD printing system 100 depicted in FIG. 1 corresponds to an additive manufacturing process in which a build material is solidified in layers based on a reflected high intensity light that is directed toward the print bed 122. In some examples, the print bed 122 contains a metal powder (e.g., powder at least partially composed of SS316, AlSi₁₀MG, TiAl₆V₄, etc.), in which the aforementioned light incident regions 124a, 124b, 124c, 124d define solidified portions for the layer forming of the solid object.

In some examples, sizes of the particles of the metal powder range from 30 to 40 microns. In some examples, the light source 104 is implemented as a flash lamp that supports a flash rate of approximately 0.3 to 1.0 hertz (Hz). However, other flash rates and/or flash sources can be implemented in other examples. Additionally or alternatively, light emitted from the light source 304 is pulsed and/or strobed. In other examples, other types of materials or combination of materials can be solidified such as, but not limited to, polymers, ceramics, plastics, nylon, etc.

Further, in the example configuration shown in FIG. 1, the micro-mirror assemblies 108d, 108e are angled to not reflect light toward the print bed 122, thereby defining regions of the print bed 122 that are not solidified (e.g., non-printed regions) when the DMD printing system 100 is used in this configuration to form a layer of an object.

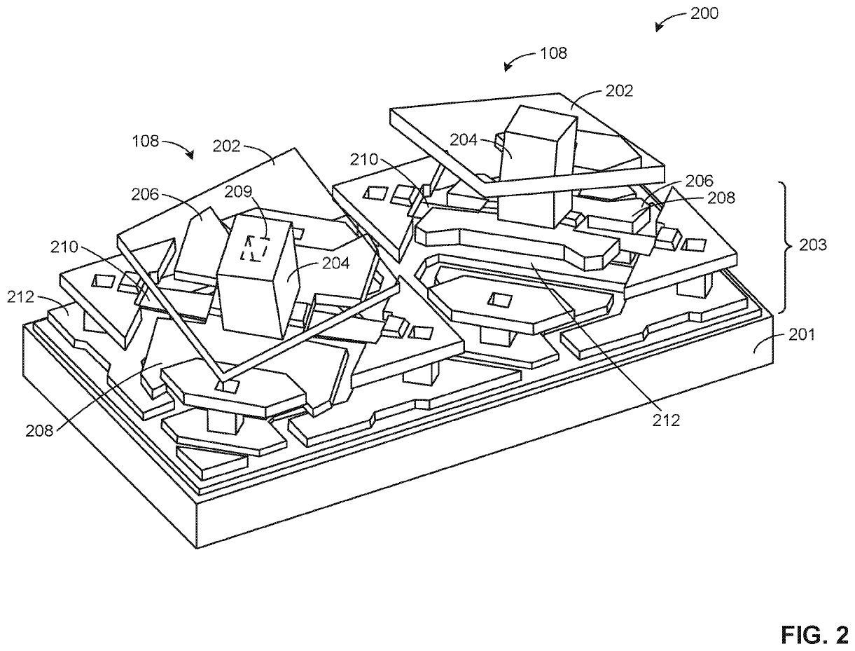

FIG. 2 is detailed view of an example micro-mirror array 200 in accordance with the teachings of this disclosure. The example micro-mirror array 200 can be used to implement the micro-mirror array 106 described and shown in connection with FIG. 1. In this example, the micro-mirror array 200 includes the micro-mirror assemblies 108, both of which are mounted to a complementary metal-oxide-semiconductor (CMOS) substrate 201 via a respective mount (e.g., a movable heatsink) 203. Each of the mounts 203 includes a micro-mirror (e.g., a mirror plate, a reflective component, a reflector, etc.) 202, a mounting pedestal (a mirror pedestal, a mirror post, etc.) 204, a yoke (e.g., a yoke plate) 206 with a landing tip 208, a hinge (e.g., a torsion hinge, a rotational hinge, etc.) 210 and a yoke pedestal 212.

To vary an angular rotation of at least one of the micro-mirror assemblies 108, movement signals of the CMOS substrate 201 cause the yoke 206 to rotate about the hinge 210, which is implemented as a torsion hinge in this example. Further, the landing tip 208 prevents the mirror plate 202 from rotating beyond a desired range based on kinematic motion of the yoke 206. In this example, the micro-mirror assemblies 108 are toggled between projecting and dumping light based on the controlled orientation of the respective micro-mirrors 202.

In some examples, the micro-mirror 202 is applied with a highly reflective coating, such as, for example, a metallic or dielectric coating. In some examples, the micro-mirror assemblies 108 are fabricated using a silicon fabrication process (e.g., a multi-stage semiconductor fabrication process). In some examples, the mounting pedestal 204 is contiguous (e.g., does not include an internal opening or void). In other examples, the mounting pedestal 204 includes an internal opening or void (e.g., a central aperture, etc.) 209. In such examples, the opening 209 can be implemented to improve manufacturability and/or vary a conductional cooling profile of the corresponding micro-mirror assembly 108. In some examples, the hinge 210 automatically centers an orientation of the micro-mirror 202 (e.g., a centered or non-rotated orientation) due to a lack of a movement signal from the CMOS substrate 201.

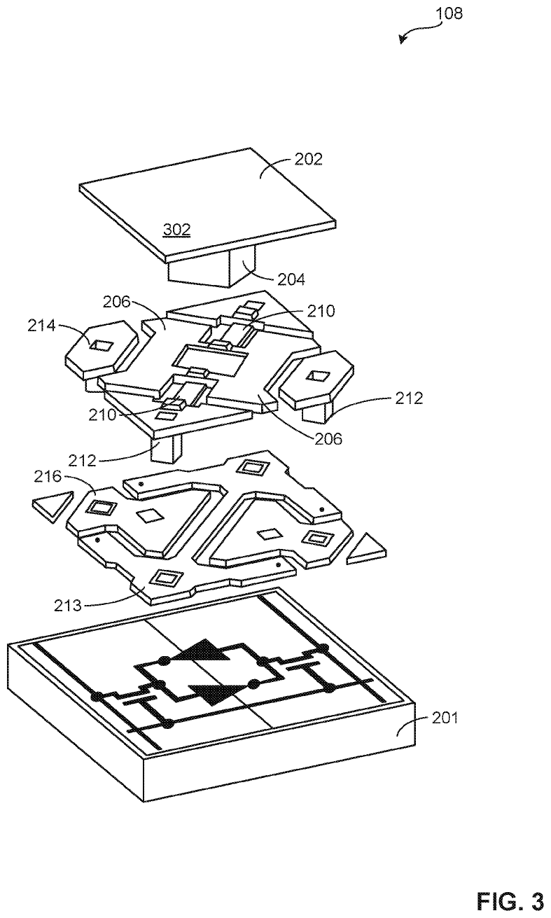

FIG. 3 is an exploded detailed view of the example micro-mirror assembly 108 of the micro-mirror array 200 of FIG. 2. As can be seen in the illustrated view of FIG. 3, the micro-mirror 202 defines a reflective surface or reflective surface area 302, and the pedestal 204 extends away from the micro-mirror 202 and toward the yoke 206. Further, the hinge 210 is shown coupled to the yoke 206. Moreover, the yoke pedestal 212, which mounts the yoke 206, is shown disposed between the yoke 206 and a bias/reset bus 213 that, in turn, contacts the CMOS substrate 201. In this example, a mirror address electrode 214 is located proximate the yoke 206, and a yoke address electrode 216 is underneath the mirror address electrode 214. The mirror address electrode 214 and the yoke address electrode 216 enable the CMOS substrate 201 to control movement of the micro-mirror assembly 108 (e.g., toggle the micro-mirror assembly 108 between light projecting and light dumping).

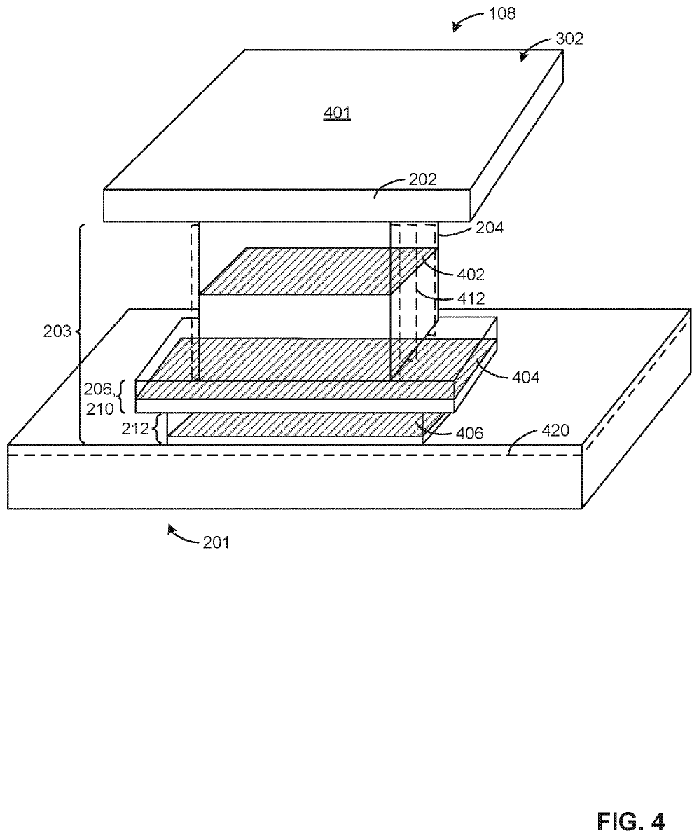

FIG. 4 is a schematic diagram of the example micro-mirror assembly 108 of the micro-mirror array 108 shown in FIGS. 2 and 3. According to the illustrated view of FIG. 4, the micro-mirror 202 has the example mount 203 and includes a surface area 401 defined by the reflective surface 302. In this example, the pedestal 204 defines a cross-sectional area 402 while the yoke 206 and/or the hinge 210 define a cross-sectional area 404. Similarly, the yoke pedestal 212 defines a corresponding cross-sectional area 406.

According to the illustrated example, the mounting pedestal 204, the yoke 206, the hinge 210 and the yoke pedestal 212 of the mount 203 define a conductive pathway of heat away from the mirror 202 and toward the CMOS substrate 201. The conductive pathway of heat flows from the micro-mirror 202, and through the pedestal 204, the hinge 210, and the yoke pedestal 212 before flowing into the CMOS substrate 201, in this example.

According to the illustrated example, each of the cross-sectional areas 402, 404, 406 are at least 30% of the surface area 401. However, the aforementioned percentage is only an example, and other example cross-sectional percentages can be implemented in other examples (e.g., equal to or greater than 45%, 50%, 55%, 60%, 65%, 75%, 80%, 85%, 90%, 95%, 100%, etc.). As a result, a relatively large heat flux can move efficiently between the mirror 202 and the CMOS substrate 201. In other words, the mount 203 of the illustrated example operates as a movable heat sink to cool the micro-mirror 202 even when the micro-mirror 202 absorbs energy form high intensity light. While the increased cross-sectional size of the mount 203 can prevent the micro-mirror 202 from being rotated and/or moved at a relatively high rate of movement, 3-D printing (e.g., 3-D metal printing) can be implemented with relatively slow movement of the micro-mirror 202 as layers of a printed object are being solidified. Accordingly, the aforementioned slow relative movement of the micro-mirror 202 in this example implementation is counterintuitive to DMD systems used for projecting images or video with relatively fast mirror movement.

In some examples, a conductive plate (e.g., a metal conductive plate and/or layer, a metal plate, etc.) 420 is disposed between the yoke pedestal 212 and the CMOS substrate 201. In such examples, the conductive pathway of heat flows from the micro-mirror 202, and through the pedestal 204, the hinge 210, the yoke pedestal 212 and the conductive plate 420 before flowing into the CMOS substrate 201. Additionally or alternatively, fins 412 are defined on and/or extend from the mounting pedestal 204, the yoke 206, the hinge 210 and/or the yoke pedestal 212 to increase a cooling surface area of the mount 203, in some examples.

An example apparatus includes a micro-mirror having a reflective surface area, and a movable mount to support and move the micro-mirror to direct light onto a printing area, where the movable mount includes a cross-sectional profile area that is at least 30% of the reflective surface area of the micro-mirror.

In some examples, the apparatus further includes a flash lamp to generate the light.

In some examples, the light generated by the flash lamp is to have a peak intensity of 1 kilowatt per centimeter squared or greater.

In some examples, the cross-sectional profile area of the movable mount is greater than 50% of the reflective surface area.

In some examples, the reflective surface area includes a metallic or dielectric coating.

In some examples, the apparatus further includes a metal plate proximate or disposed in a complementary metal-oxide-semiconductor (CMOS) substrate coupled to the movable mount.

An example apparatus includes a micro-mirror having a reflective surface area, and a movable heatsink coupled to the micro-mirror, where the movable heatsink is to move the micro-mirror to reflect light from a light source toward a print area and provide a conduction heat path for the micro-mirror.

In some examples, the light reflected by the micro-mirror has a peak intensity that is at least 1 kilowatt per centimeter squared.

In some examples, the movable heatsink includes a cross-sectional profile area that is at least 30% of the reflective surface area of the micro-mirror.

In some examples, the movable heatsink includes fins to increase a cooling surface area of the movable heatsink.

In some examples, the movable heatsink includes a yoke plate and a torsion hinge.

An example printer includes a light source, and a digital micro-mirror device (DMD) to reflect light from the light source. The DMD includes a micro-mirror having a reflective surface area, and a movable mount to support and move the micro-mirror, where the movable mount includes a cross-sectional profile area that is at least 30% of the reflective surface area of the micro-mirror, and where the light is to be reflected from the DMD toward a metal powder bed disposed in a print area to print a metal object.

In some examples, the movable mount includes fins.

In some examples, the cross-sectional profile area of the movable mount is greater than 65% of the reflective surface area.

In some examples, the reflective surface area includes a metal or dielectric coating.

Example methods, apparatus and articles of manufacture have been disclosed that enable photonic 3-D printing of metal by providing effective thermal dissipation of heat energy away from micro-mirrors due to high intensity light. Accordingly, the relatively high light intensities that coincide with photonic metal printing can be accommodated with DMD implementations.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

What is claimed is:

1. An apparatus comprising:
a micro-mirror having a reflective surface area; and
a movable mount to support and move the micro-mirror to direct light onto a printing area, wherein the movable mount includes a cross-sectional profile area that is at least 30% of the reflective surface area of the micro-mirror.

2. The apparatus as defined in claim 1, further including a flash lamp to generate the light.

3. The apparatus as defined in claim 2, wherein the light generated by the flash lamp is to have a peak intensity of 1 kilowatt per centimeter squared or greater.

4. The apparatus as defined in claim 1, wherein the cross-sectional profile area of the movable mount is greater than 50% of the reflective surface area.

5. The apparatus as defined in claim 1, wherein the reflective surface area includes a metallic or dielectric coating.

6. The apparatus as defined in claim 1, further including a metal plate proximate or disposed in a complementary metal-oxide-semiconductor (CMOS) substrate coupled to the movable mount.

7. An apparatus comprising:
a micro-mirror having a reflective surface area; and
a movable heatsink coupled to the micro-mirror, the movable heatsink to move the micro-mirror to reflect light from a light source toward a print area and provide a conduction heat path for the micro-mirror.

8. An apparatus as defined in claim 7, wherein the light reflected by the micro-mirror has a peak intensity that is at least 1 kilowatt per centimeter squared.

9. An apparatus as defined in claim 7, wherein the movable heatsink includes a cross-sectional profile area that is at least 30% of the reflective surface area of the micro-mirror.

10. The apparatus as defined in claim 7, wherein the movable heatsink includes fins to increase a cooling surface area of the movable heatsink.

11. The apparatus as defined in claim 7, wherein the movable heatsink includes a yoke plate and a torsion hinge.

12. A printer comprising:
a light source; and
a digital micro-mirror device (DMD) to reflect light from the light source, the DMD including:
a micro-mirror having a reflective surface area, and
a movable mount to support and move the micro-mirror, wherein the movable mount includes a cross-sectional profile area that is at least 30% of the reflective surface area of the micro-mirror, and wherein the light is to be reflected from the DMD toward a metal powder bed disposed in a print area to print a metal object.

13. The printer as defined in claim 12, wherein the movable mount includes fins.

14. The printer as defined in claim 12, wherein the cross-sectional profile area of the movable mount is greater than 65% of the reflective surface area.

15. The printer as defined in claim 12, wherein the reflective surface area includes a metal or dielectric coating.
